(19) United States
(12) Patent Application Publication
(10) Pub. No.: US 2019/0312544 A1
(43) Pub. Date: Oct. 10, 2019

(54) SUN TRACKING SOLAR SYSTEM

(71) Applicant: BOLYMEDIA HOLDINGS CO. LTD, Santa Clara, CA (US)

(72) Inventor: Xiaoping HU, Shenzhen (CN)

(73) Assignee: BOLYMEDIA HOLDINGS CO. LTD, Santa Clara, CA (US)

(21) Appl. No.: 16/306,549

(22) PCT Filed: Jun. 2, 2016
(86) PCT No.: PCT/CN2016/084503

§ 371 Date: Nov. 30, 2018

(51) Int. Cl. H02S 20/32; F24S 50/20; H02S 40/44; H01L 35/30; H02S 40/42

(52) U.S. Cl. CPC H02S 20/32; F24S 50/20; H02S 40/425; H01L 35/30; H02S 40/44

(57) ABSTRACT

Provided is a sun tracking solar system, comprising a light focusing device and a solar energy utilization device. The system further comprises a drive mechanism (130), or further comprises a light guide device (240) and a drive mechanism (230). The drive mechanism is configured to drive a light-receiving surface to move with the sun. The light-receiving surface receives sunlight after convergence thereof by the light focusing device, and the driven light-receiving surface may be a light-receiving surface of the light energy utilization device (120), and may further be a light-receiving surface of the light guide device (240) located between the light focusing device (210) and the light energy utilization device (220). Since the driven surface is the light-receiving surface after light convergence, an area of the driven surface is usually less than an area of an original light-receiving surface. This simplifies a structure of the drive mechanism, reduces difficulty in sun tracking, energy consumption, and costs, and expands the application scope of a sun tracking solar system, or enhances the production efficiency of a sun tracking solar system.

### TECHNICAL FIELD

The present disclosure relates to clean energy, and in particular, to sun tracking solar systems capable of tracking solar motion.

### BACKGROUND OF THE INVENTION

With increasing emphasis on environmental protection, solar systems are growing in popularity. Many solar systems have currently adopted solar tracking systems. A solar tracking system is mainly used to adjust the orientation and the attitude of a solar system with changes of solar position, so that when the coverage area thereof is limited sunlight can be received as much as possible.

An existing solar tracking system is mainly carried out by driving the original light-receiving surface of the solar system. Such tracking manner is used mainly as a result of the input energy of the solar system determined by the area and orientation of the original light-receiving surface. The term “original light-receiving surface” refers to the surface of the solar system that initially receives sunlight. For a simple solar system, it may be the light-receiving surface itself of a light energy utilization device (such as a photovoltaic panel); and for a solar system provided with a light-condensing member, it may be the first light-receiving surface of the light-condensing member. For the sake of simplicity, photovoltaic panels are used to represent various photovoltaic conversion devices, including polycrystalline silicon photovoltaic panels, monocrystalline silicon photovoltaic panels, amorphous silicon photovoltaic panels, III-V semiconductor photovoltaic panels, copper indium gallium selenide (CIGS) photovoltaic panels, perovskite-type photovoltaic panels, photovoltaic films and the like.

The original light-receiving surface of a solar system often has a large area, so it is usually driven in a direct way with a precondition for a relatively complicated driving mechanism to track the movement of the sun. In addition, to add the area of light receiving, a plurality of original light-receiving surfaces may also be needed in the solar system; in this way, a plurality of corresponding driving units may be provided respectively, resulting in an increase in cost.

### SUMMARY OF THE INVENTION

The sun tracking solar system according to the present disclosure may include a light focusing device and a solar energy utilization device. The light focusing device is configured for condensing sunlight incident along an incident light path thereof; and the solar energy utilization device is arranged on the light path behind the light focusing device and configured for utilizing the received light energy. The system may include a drive mechanism or include a light guide device and a drive mechanism. The drive mechanism is configured for driving a light-receiving surface to move with the sun. The sunlight received by the light-receiving surface is the one which has been concentrated by the light focusing device. The driven light-receiving surface may be the light-receiving surface of the solar energy utilization device, or the light-receiving surface of the light guide device arranged between the light focusing device and the solar energy utilization device. The so-called light guide device is configured to guide the sunlight condensed by the light focusing device to the solar energy utilization device.

In the sun tracking solar system according to the present disclosure, since the driven light-receiving surface is the one corresponding to the sunlight which has been converged, its area is usually much smaller than the area of the light-receiving surface. This may simplify the structure of the drive mechanism, reduce the difficulty and energy consumption of sun tracking, and expand the application scope of sun tracking solar system.

Specific examples according to the present disclosure will be described in detail below with reference to the accompanying drawings.

### BRIEF DESCRIPTION OF THE DRAWINGS

FIG. 1 is a schematic diagram of a Fresnel-type reflection lens according to the present disclosure;

FIG. 2 is a schematic diagram of the solar system of a first embodiment;

FIG. 3 is a schematic diagram of the solar system of a second embodiment;

FIG. 4 is a schematic diagram of the solar system of a third embodiment;

FIG. 5 is a schematic diagram of the solar system of a fourth embodiment;

### DETAILED DESCRIPTION

A sun tracking solar system according to the present disclosure may include a light focusing device and a solar energy utilization device.

The light focusing device is used for condensing sunlight incident along an incident light path thereof. As a preferred embodiment, the light focusing device in the solar system according to the present disclosure may be a Fresnel lens. For ease of understanding, related terms will be firstly described below.

The Fresnel lens is a thin lens. It can be produced by means of dividing the continuous original surface of a conventional lens into several sections, reducing the thickness of each section, and then placing all the thin sections on an identical plane or an identical substantially-smooth curved surface. Such discontinuous refracting surfaces evolved from the original curved surface can be referred to as a Fresnel refractive surface which is generally stepped or toothed. Theoretically the Fresnel refractive surface may have approximate optical properties compared to the corresponding original surface, but its thickness is greatly reduced. The Fresnel refractive surface generated by a single original curved surface can be referred to as a Fresnel unit.

The original curved surface commonly used for generating the Fresnel refractive surface is generally a curved surface symmetrically around an optical axis, such as a spherical surface, a rotating paraboloid and other rotary surfaces. The focus of a conventional original curved surface is at one point, so it can be referred to as a “concurrent plane”. In the present disclosure, the original curved surface can be any type of coaxial surface, and can be specifically configured according to actual needs. The so-called coaxial surface refers to curved surfaces having focus on an identical line (not necessarily at an identical point). This line can be referred to as a “coaxial line”. The conventional concurrent plane can be regarded as a special case when the coaxial line of the coaxial surface degenerates to a point. With an original curved surface that is coaxial but non-concurrent, a sensing element provided at a focus position can be expanded from a smaller area (corresponding to the focus) to a long strip (corresponding to the coaxial line made up of the focus), thus enhancing the ability to collect signal and helping to solve local overheating issues without significantly increasing costs. Typical coaxial surfaces include rotating surfaces (containing secondary or higher-order rotating surfaces), cylindrical surfaces, conical surfaces and so on. The cylindrical surfaces, which can also be referred to as uniform section coaxial surfaces, have the same shapes and sizes of cross sections which are obtained after being cut at any point along the vertical direction of the coaxial line. A circular cylindrical surface is a special case of the cylindrical surface. The conical surfaces have cross sections with a similar shape but different sizes. A circular conical surface is a special case of the conical surface.

A “macro” refracting surface composed of one or more Fresnel units may be referred to as a tooth surface, and a substantially smooth or flat surface opposite thereto may be referred to as a reverse side. The tooth surface containing only one Fresnel unit can be referred to as a “simple Fresnel refracting surface”, and the tooth surface containing two or more Fresnel units can be referred to as a “composite Fresnel refracting surface”. Generally, the basic parameters of each Fresnel unit on the composite Fresnel refracting surface (e.g. area, focal length, shape of the corresponding original surface, number of concentric rings used for dividing the original surface, etc.) can be arranged flexibly and can be identical, partially identical, or completely different. It can be considered that these Fresnel units are arranged on a “macro” surface such as a plane, a quadratic surface (including a spherical surface, an ellipsoidal surface, a cylindrical surface, a parabolic cylinder, a hyperbolic cylinder), a high-order polynomial surface (which is a usual way to implement aspheric surface), a folding or terraced surface formed by splicing a plurality of planes, and the like.

Generally speaking, various types of elements can be made by flexibly combining the tooth surface with the reverse side. For example, a Fresnel lens having a tooth surface and a reverse side may be referred to as a “single-sided Fresnel lens”. A Fresnel lens having both sides of tooth surfaces can be referred to as a “double-sided Fresnel lens”. In addition, as to a variation of the double-sided Fresnel lens, if one tooth surface thereof is a “simple Fresnel refracting surface”, it may be replaced by a conventional convex lens surface or a conventional concave lens surface.

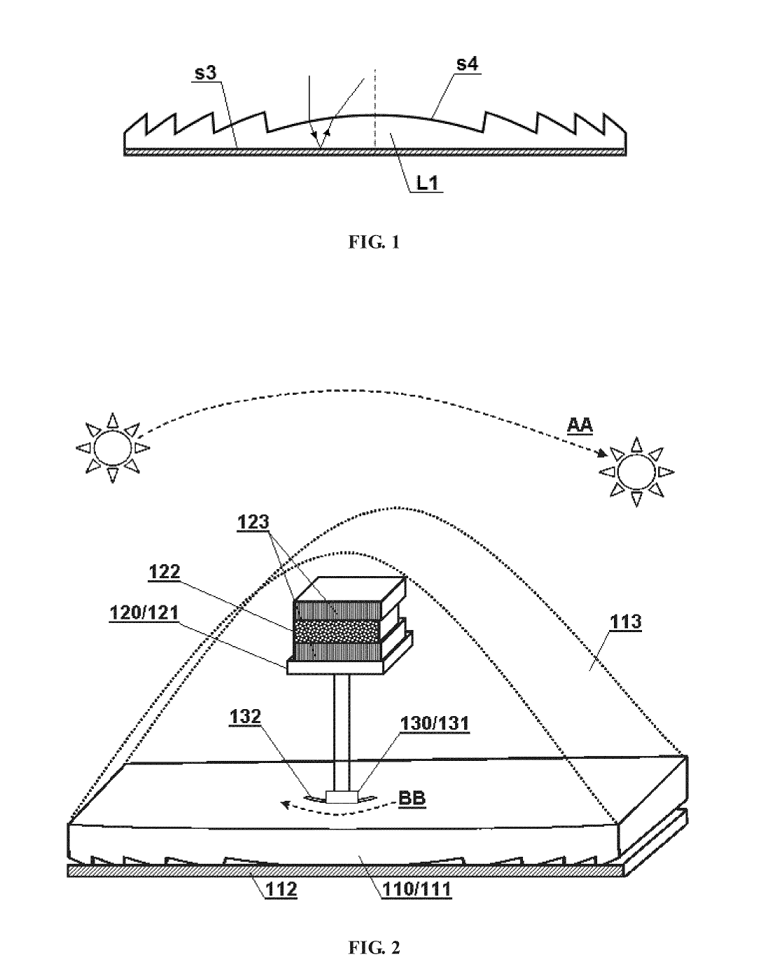

The reflecting surface adopted in the light focusing device of the present disclosure may be a planar reflecting surface or a curved reflecting surface, such as a concave or convex reflecting surface, and may also be a reflecting surface in a tooth surface shape. The reflecting surface may be combined with the refracting surface and provided by a reflection lens. The so-called reflection lens is a lens having a reflection coating on its one side. The reflecting surface may be coincided with a light-focusing refracting surface; in this way, the other side of the reflection lens facing in a direction in which the sunlight is incident may be a planar surface, a concave surface, a convex surface or a tooth surface. The reflecting surface may be arranged at another side opposite to the light-focusing refracting surface; in this way, the light-focusing refracting surface faces in a direction in which the sunlight is incident. As a preferred embodiment, with reference to FIG. 1, the reflecting surface may be provided by a Fresnel-type reflection lens, which may be regarded as a combination of Fresnel lens and a reflecting surface. As shown in FIG. 1, an element L1 has a reflecting surface s3 and a Fresnel refracting surface s4, the sunlight is refracted from the refracting surface into the lens and then reflected by the reflecting surface, and is again refracted out of the element through the refracting surface. The incident light path, due to the reflection, passes through the physical refracting surface s4 which actually equivalent to two tooth surfaces, therefore the convergence effect of the system can be advantageously enhanced by arranging the reflecting surfaces.

The light focusing device adopted in the present disclosure may be formed by jointing a plurality of light-focusing modules together in a predetermined pattern. Each light-focusing module may include a tooth surface and a reflecting surface. The entire tooth surfaces of the jointed light focusing device may be a “composite Fresnel refracting surface”, parts of which are included by the light-focusing modules respectively. For example, in one embodiment, each light-focusing module may include a simple Fresnel refracting surface generated by a single original curved surface, which may reduce the difficulty in fabricating the light-focusing module and facilitate large-area installation. In another embodiment, multiple composite Fresnel refracting surfaces may be included in the light-focusing modules respectively and then be jointed with each other to form a tooth surface having a larger area. In still another embodiment, the light-focusing module may only include one Fresnel unit which is from a part of a single original curved surface, and the plurality of light-focusing modules may be jointed together to obtain a tooth surface corresponding to an integral original curved surface. The pattern and the curved surface's macroscopic form the entire tooth surface of the light focusing device, as well as the dividing manner of the light-focusing modules can be designed according to desired optical parameters, including a desired focal length, coverage area and the like.

In a specific implementation, the light-focusing module may be composed of two parts, namely a lens and a base supporting the lens. One surface of the lens adjacent to the base is the reflecting surface. In other words, the reflecting surface and the tooth surface can be provided in one and the same element, for example, it can be realized by coating the back surface of the Fresnel lens with a reflective film; and the reflecting surface and the tooth surface can be provided on different elements, for example, a reflected plate may be provided or a reflective film may be coated at the surface of the base facing toward the light-focusing lens.

The solar energy utilization device is provided on the light path behind the light focusing device for utilizing the received light energy. Herein, the solar energy utilization device may include an apparatus capable of converting light energy into other kinds of energy, such as a photovoltaic conversion device (e.g. a photovoltaic panel), a photothermal conversion device (e.g. a solar vacuum tube) and the like; it may also include an apparatus capable of storing generated energy such as a thermal energy storage device; and it may further include an apparatus capable of utilizing the generated energy such as a thermal energy utilization device (e.g. a device using temperature difference for power generation, a thermoelectric generator, etc.)

The solar energy utilization device adopted in the present disclosure may include only a simple light-energy conversion device, such as a photovoltaic panel, or it may be a composite device composed of a plurality of types of solar energy utilization device so as to achieve full utilization of light energy. For example, a photoelectric conversion device for receiving sunlight and a thermal energy utilization device for collecting and utilizing thermal energy generated by the photoelectric conversion device may be simultaneously included.

Preferably, the photoelectric conversion device may be wrapped in the thermal energy utilization device so that heat can be sufficiently absorbed and utilized. For example, the photoelectric conversion device may be of a closed type, and the closed type means that the sunlight is substantially enclosed therein after entering the device through a light guiding element without being arbitrarily lost. For example, the inner wall of the photoelectric conversion device may be composed of a photovoltaic panel, or it may be composed of a photovoltaic panel and a reflector. The outer wall thereof can be metal or thermoelectric conversion apparatus.

Preferably, at least one thermoelectric conversion apparatus may also be included for utilizing the conducted thermal energy to generate electricity. It may be provided at a heat conduction path between the photovoltaic conversion apparatus and the thermal energy utilization device, or at a heat conduction path between the thermal energy utilization device and an external cooling device. The cooling device used may be selected from the group consisting of a water tank, a steam power generation system, a seawater desalination system, a seawater desalination and power generation system, a closed thermal cycle power generation system and the like.

It should be noted that since the light energy utilization device can be designed to include many components according to the needs of a specific application, the so-called “drive the solar energy utilization device to move” should be understood as driving the light-receiving surface of the solar energy utilization device to move for receiving the sunlight.

The sun tracking solar system according to the present disclosure may further include a drive mechanism, or may further include a light guide device and a drive mechanism.

The drive mechanism is configured to drive a light-receiving surface to move with the movement of the sun. The sunlight received by the light-receiving surface is the one which has been concentrated by the light focusing device. The driven light-receiving surface may be the light-receiving surface of the solar energy utilization device, or the light-receiving surface of the light guide device arranged between the light focusing device and the solar energy utilization device. The so-called light guide device is configured to guide the sunlight condensed by the light focusing device to the solar energy utilization device. Because the driven light-receiving surface is the one corresponding to the sunlight which has been converged, its area is usually much smaller than the area of the light-receiving surface. This may simplify the structure of the drive mechanism, reduce the difficulty and energy consumption of sun tracking, and expand the application range of sun tracking solar system. In addition, since the movement range of the converged sunlight is greatly decreased, the drive mechanism can track the movement of the sun by simply driving; for example, the drive mechanism can drive the condensed light-receiving surface to move along a preset orbit, or to rotate, or to move in a straight line, etc.

Several modes of use of the sun tracking solar system according to the present disclosure will be described below by way of examples with some specific scenarios.

### First Embodiment

Referring to FIG. 2, a solar system according to an embodiment of the present disclosure may include a light focusing device 110, a solar energy utilization device 120 and a drive mechanism 130.

The light focusing device 110 may include a Fresnel lens 111 and a reflected plate 112 which are sequentially arranged in the incident direction of the sunlight. The reflected plate can also be regarded as a base for supporting the Fresnel lens. The tooth surface of the Fresnel lens 111 faces downward and is adjacent to the reflecting surface of the reflected plate, and the back surface of the Fresnel lens is a smooth concave surface. In other embodiments, the reflected plate can also be replaced by a reflective coating on the tooth surface of the Fresnel lens 111.

As a preferred embodiment, the light focusing device in this embodiment may further include a light transmitting shield 113 provided at the forefront of the light focusing device along the incident direction of the sunlight for closing the light focusing device and the solar energy utilization device, blocking them from dust, rain, air pollution and the like so as to slow down the aging of the device. In other embodiments, other types of front end optical elements may also be employed. For example, the shield may further have a function of converging sunlight to serve as a primary light-focusing lens, facilitating the acquirement of more solar energy.

The solar energy utilization device 120 may include a photovoltaic conversion apparatus 121, a thermal energy storing apparatus 122 and two thermoelectric conversion apparatus 123. The light-receiving surface of the photovoltaic conversion apparatus 121 faces downward, one of the thermoelectric conversion apparatus is arranged on the heat conduction path between the photovoltaic conversion apparatus and the thermal energy storing apparatus, and the other one is arranged on the heat dissipation surface of the thermal energy storing apparatus. In other embodiments, the solar energy utilization device may be selected and combined according to actual needs, for example, it may be a combination of a photovoltaic panel and a steam power generation device, or a combination of a photovoltaic panel and a water heater or a thermal power generation device or a seawater desalination device.

The drive mechanism 130 may include a sliding support structure 131 and a rail 132. The sliding support structure 132 is movable along the rail 131, and the light-receiving surface of the photovoltaic conversion apparatus 121 is fixed to the top end of the sliding support structure 132. When the sun moves along the path AA, the trajectory of the focus of the light focusing device is basically a curve, such that the tracking of the sun can be realized by designing a corresponding rail according to this curve. For example, in the present embodiment, the light-receiving surface of the photovoltaic conversion apparatus can always receive the concentrated sunlight by moving the sliding support structure along a path BB determined by the rail.

In this embodiment, the drive mechanism 130 is arranged at the bottom of the support structure, and the photovoltaic conversion apparatus is moved by driving the support structure. In other embodiments, the support structure may also be fixed, and the drive mechanism is arranged at the top of the support structure, that is, the rail and the sliding component are arranged at one end at which the support structure connects with the photovoltaic conversion apparatus, and photovoltaic conversion apparatus is directly driven to move.

As a preferred embodiment, the three light-receiving surfaces of the light focusing device i.e. the smooth concave surface, the tooth surface and the reflecting surface in this embodiment may be designed to have a common focus. In this way, when the light-receiving surface of the solar energy utilization device, is in the vicinity of the focus, there will have almost no reflection loss for the solar system, because the sunlight reflected by the light-receiving surface of the solar energy utilization device (e.g. a photovoltaic panel) may be reflected back again by the reflecting surface of the light focusing device to be fully utilized.

Since the superficial area of the light focusing device is usually relatively large, in order to facilitate mass production, the lens used, such as a Fresnel lens, may be formed by hot-press using glass or a transparent plastic material. The transparent plastic material can be selected from the group consisting of polymethyl methacrylate (PMMA, commonly known as acrylic), polycarbonate (PC), polycarbonate/polybutylene terephthalate (PC/PBT) mixture, acrylonitrile-Butadiene-styrene copolymer (ABS), and silica gel. It is more convenient and safer to make a lens using a plastic material than in the case of glass (for example, in the case of mounting on a roof). However, the ordinary plastic material has poor anti-aging properties. And therefore, preferably, a layer of transparent anti-aging coating may further be arranged on the light-receiving surface of the transparent plastic material. Materials that can be used as anti-aging coatings include: polyvinylidene fluoride (PVDF), ethylene-tetrafluoroethylene copolymer (ETFE), tetrafluoroethylene-perfluoroalkoxy vinyl ether copolymer (PFA), high quality Silicone, metal coating, etc.

The solar system of the present embodiment can be used on a road surface, a water surface or a roof of a building. It achieves tracking of the sun with a simple drive structure, which can reduce system cost. Moreover, such reflection and concentration method can effectively reduce or even eliminate the reflection loss of solar energy, thereby improving the utilization rate of solar energy and reducing light pollution.

### Second Embodiment

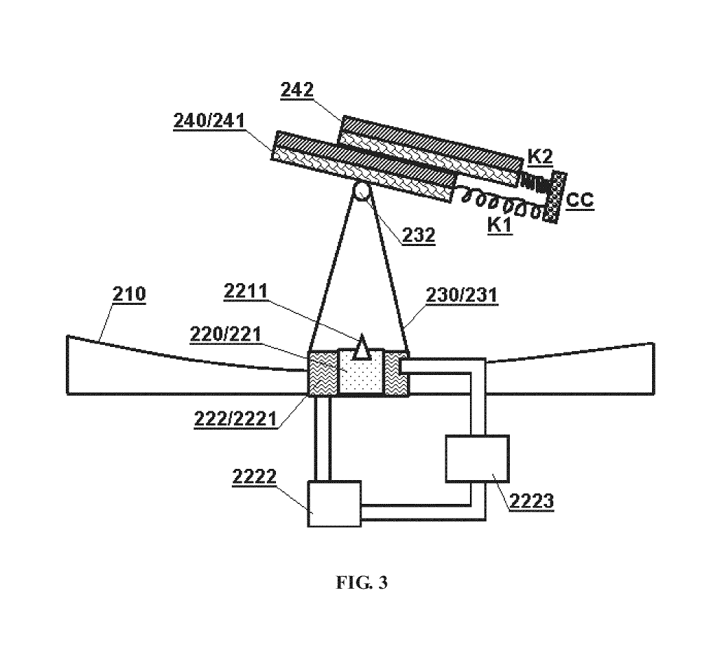

Referring to FIG. 3, a solar system according to another embodiment of the present disclosure may include a light focusing device 210, a solar energy utilization device 220, a drive mechanism 230 and a light guide device 240.

The light focusing device 210 may be a simple concave reflector which is made of ordinary plastic, and is coated with a reflective film firstly on the its light-receiving surface and then coated with a transparent anti-aging layer.

The solar energy utilization device 220 may include a photovoltaic conversion apparatus 221 having a closed cavity and a thermal energy utilization device 222 wrapped around the periphery of the photovoltaic conversion apparatus. In this embodiment, the inner wall of the photovoltaic conversion apparatus 221 is composed of a photovoltaic panel and a reflective mirror. A beam splitter 2211 is further arranged at the entrance of the sunlight path to prevent the sunlight incident into the closed cavity from being reflected to the outside of the cavity as much as possible. The thermal energy utilization device 222 may include a liquid gasification chamber 2221, a gas turbine generator 2222 and a compressor 2223 which are connected by a pipe with a valve (not shown). The working medium in the thermal energy utilization device may be water, freon, or other substances having a lower vaporization temperature.

The light guide device 240 may include two reflection lenses 241, 242 (e.g. reflection-type Fresnel lens) in an overlapping pattern. The end of the reflection lens 241 at the front is connected to a junction piece CC via a spring K1, the end of the reflection lens 242 at the rear is connected to the junction piece CC via a spring K2, and the lens 242 can be slidable on the lens 241. The sunlight concentrated by the light focusing device 210 can irradiate onto the lens 241 or 242, and then, after being concentrated once more and reflected again, be guided to the entrance of the sunlight path of the photovoltaic conversion apparatus 221.

The drive mechanism 230 may include a support structure 231 and a rotating shaft 232. The support structure 231 is fixed relative to the solar energy utilization device and may be made of a light-transmitting material or have a thin frame structure, so as not to affect the sunlight incident on the solar energy utilization device as much as possible. The reflection lens 241 is rotatably fixed to the top of the support structure by the rotating shaft 232.

When the reflection lens 241 is in a horizontal position, the reflection lens 242 is reset to a position behind the reflection lens 241 by the action of the two springs K1, K2, and the reflection lenses 242, 241 are overlapped so as not to block the incident sunlight as much as possible; in this way, the springs K1, K2 are in a natural state. When the lens 241 is driven by the rotating shaft to be leaned to the right, the lens 242 may slide to the right side by gravity, thereby expanding the light-receiving surface of the light guide device to the right; in this way, the spring K1 is stretched and the spring K2 is compressed. When the lens 241 is driven by the rotating shaft to be leaned to the left, the lens 242 may slide to the left side by gravity, thereby expanding the light-receiving surface of the light guide device to the left; in this way, the spring K2 is stretched and the spring K1 is compressed.

FIG. 3 shows a second embodiment of the present disclosure, which is another flexible driving method of the drive mechanism according to the present disclosure, i.e., a driving manner in which rotation driving and translation are combined. In this embodiment, the drive mechanism of the present disclosure does not directly drive the light energy utilization system, but rather a light energy relay.

This embodiment embodies the flexibility of the drive mechanism of the present disclosure. In addition to directly driving the light-receiving surface of the solar energy utilization device as in the first embodiment, it is also possible to achieve tracking of the sun by driving the light guide device to move. Moreover, by utilizing gravity, a simple rotational motion of the drive mechanism can produce rotational movement and relative linear movement of the light guide device.

### Third Embodiment

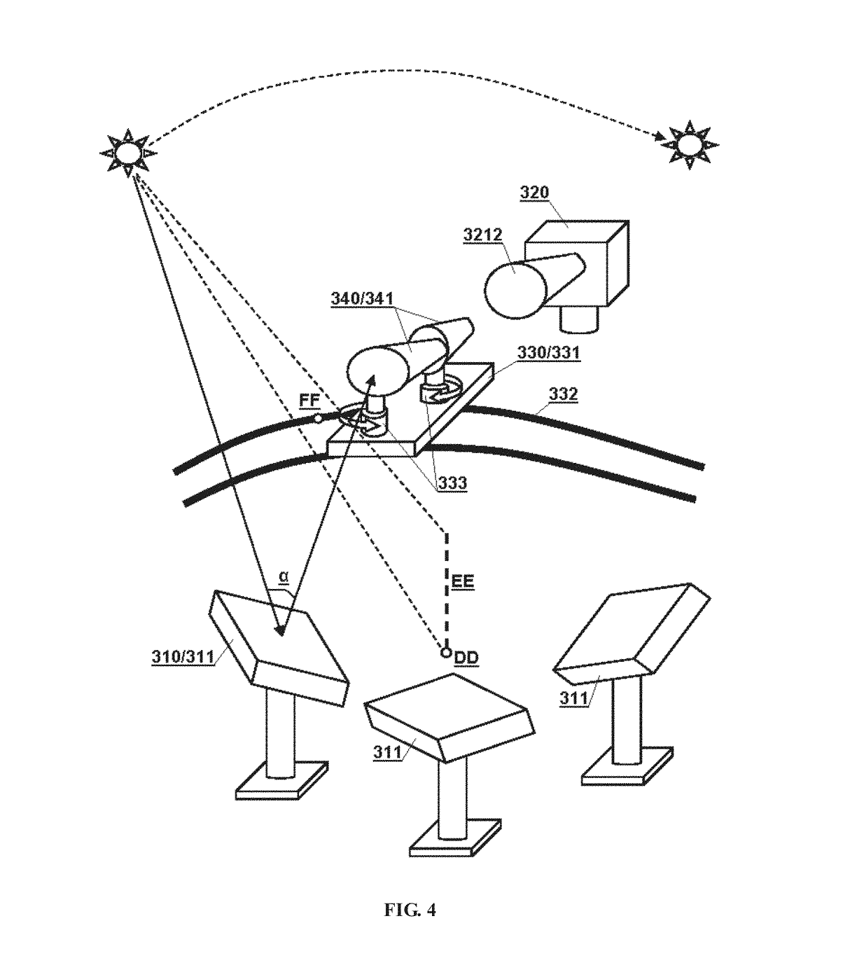

Referring to FIG. 4, a solar system according to still another embodiment of the present disclosure may include a light focusing device 310, a solar energy utilization device 320, a drive mechanism 330 and a light guide device 340.

The light focusing device 310 may include a plurality of reflecting devices 311 (the original light-receiving surfaces) that reflect and condense the sunlight to the light guide device 340. Three are schematically shown in the figure, and actually there may be more or less. As a preferred embodiment, each of the reflecting devices in this embodiment can be arranged on a conventional sun tracking system (for example, a common single-axis or dual-axis sun tracking system, which is not shown), which is very suitable for large scale of solar power plants, resulting in being able to collect as much sunlight as possible.

The entrance of the sunlight path of the solar energy utilization device 320 is preferably provided with a horn-shaped light guide 3212 so as to enlarge the area of its light-receiving surface.

The light guide device 340 may include a plurality of horn-shaped light guides 341 sequentially arranged along the optical path, and the sunlight concentrated by the light focusing device is incident from the horn mouth of a first horn-shaped light guide, and then sequentially guided to the horn mouth of the solar energy utilization device. Two horn-shaped light guides are provided in sequence in this embodiment, and the optical path may have a larger angle to be adjusted by adjusting a relative angle between the two light guides. In other embodiments, if such configuration is applied to a small system, it is also possible to use only one light guide. A reflective film is plating on the inner surface of the light guide, and a corrosion-resistant transparent protective layer may be further provided thereon.

The drive mechanism 330 may include a support structure 331, a rail 332, and a plurality of rotating shafts 333. The support structure 331 is movable integrally along the rail 332, and each light guide device is fixed to the support structure by a corresponding rotating shaft 333. In this embodiment, the moving mode of the light guide device is a combination of the movement of the rail and a rotational movement. The light guide device can either be moved along the rail as a whole, or be individually moved by adjusting the orientation of each horn-shaped light guide, so as to maximum the conducted light energy.

According to the solar system of the present embodiment, the design for tracking the sun can be simply implemented in such a manner that, for a plurality of original light-receiving surfaces arranged in a distributed manner, the light guide device can be arranged between the sun and the plurality of original light-receiving surfaces to make the original light-receiving surface be capable of reflecting most of the sunlight onto the light guide device. Therefore, the center point by which the mounting positions surround can be determined according to the installation positions of the plurality of original light-receiving surfaces on the ground (shown as a reference sign DD in the figure), and the shape of the rail 332 is designed as an arc centered on the center point (the plane in which the arc located is perpendicular to the ground). Of course, the shape of the rail 332 can also be designed as a flat curve of other shapes arranged between the sun and the plurality of original light-receiving surfaces.

When driving the light guide device integrally to move, it is only necessary to determine the plane formed by the sun and a center line EE (the center line refers to a line passing through a center point (as the reference sign DD shown in the figure) and perpendicular to the ground) and move the light guide device to an intersection FF of the plane and the rail 332. At this time, the sun, the sunlight entrance of the first light guide of the light guide device, and the center point are on one and the same plane. A conventional sun tracking system used for adjusting the posture of each original light-receiving surface may only need to adjust the normal of the original light-receiving surface to the central line of its reflection angle α. The reflection angle α refers to an angle formed by the midpoint of the original light-receiving surface and a line between the sun and the sunlight entrance of the first light guide.

The system of the present embodiment has a significant improvement compared with a solar thermal power station using the conventional sun tracking system. In the existing solar power station, the solar energy utilization device generally adopts a fixed tower structure, and the sunlight of the original light-receiving surface is directly concentrated thereon. Though the angle and the orientation of the original light-receiving surface is generally adjusted by the conventional sun tracking system to track the movement of the sun, since the heat utilization tower is generally provided at the center of each original light-receiving surface to cope with the movement of the sun, it is difficult for an existing thermosolar plant to take full advantage of the surface area of the original light-receiving surface. As a contrast, since a movable light guide device is added in this embodiment, the position of the light guide device can be adjusted to fully adapt to the movement of the sun, the sunlight guided to the solar energy utilization device is as much as possible by optimizing the reflection angle where the surface area of the original light-receiving surface is constant. Moreover, the light guide device and the drive mechanism can be realized by a simple design, the control of the motion thereof is also simple, such that the output power of the power station can be greatly improved only by a small increased cost. A solar power station that has been built can be improved according to the embodiment, and the power generation amount thereof can be effectively increased by only adding a light guide device and a corresponding drive mechanism.

This embodiment can also solve a potential safety hazard of a large-scale solar-thermal power station. When a large amount of light energy is brought together, the heat generated by it may cause a fire. There may have hundreds or thousands of condenser lenses in a large power plant. These condenser lenses may cause a fire by gathering light energy to a place that should not be gone for various reasons. In this embodiment, the light energy is first collected on a light guide device which is free of expensive equipment and can be replaced immediately; in this way, its ability to withstand disasters is greatly improved.

In the present embodiment, the original light-receiving surface need not be a planar surface, but it may be a curved surface; and therefore, the azimuth angle thereof may be represented by the normal of the original light-receiving surface at the center point.

### Fourth Embodiment

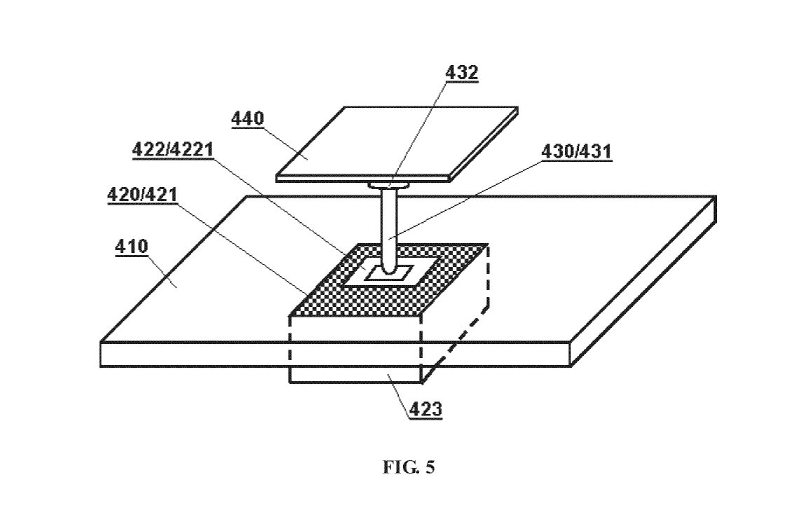

Referring to FIG. 5, a solar system according to still another embodiment of the present disclosure may include a light focusing device 410, a solar energy utilization device 420, a drive mechanism 430 and a light guide device 440.

The light focusing device 410 is a reflective light-focusing lens, for example, a Fresnel reflection lens.

The solar energy utilization device 420 includes a photovoltaic panel 421 and a thermal energy utilization device 422. In this embodiment, the thermal energy utilization device receives sunlight through a transparent heat-insulating panel 4221, and the photovoltaic panel surrounds the transparent heat-insulating panel. Both of them are arranged on the same light-receiving surface. In other embodiments, various different planar arrangements may be employed as long as the photovoltaic panel and the thermal energy utilization device each have different light receiving regions on the same light-receiving surface. Preferably, the solar energy utilization device may further comprise a thermal energy storing apparatus (or a cooling system) 423 arranged beneath the photovoltaic panel and the thermal energy utilization device.

The light guide device 440 is a reflective mirror or a reflection lens, for example, it may be a Fresnel reflection lens (wherein the Fresnel lens portion may be a concave lens or a convex lens), or it may be a planar or curved reflective mirror.

The drive mechanism 430 may include a support structure 431 and a vertical movement mechanism 432. The light guide device is fixed to the vertical movement mechanism and can move up and down along the support structure. Judging by appearance, the drive mechanism acts to adjust the focal length of the light guide device. However, since there are two different devices on the light-receiving surface, i.e., the photovoltaic panel and the transparent heat-insulating panel of the thermal energy utilization device, the adjustment of the focal length is finally the adjustment of the solar energy distribution on different solar energy utilization devices. By adjusting the energy distribution of the solar energy, the usage efficiency of the solar energy can be optimized, and the photovoltaic panel can be prevented from being damaged due to overheating.

The solar system of the present embodiment is suitable for use as an integrated solar energy utilization system that combines photovoltaic and photothermal utilization. A method of dynamically adjusting the energy distribution between photovoltaic utilization and photothermal utilization is also provided.

The principle and implementation manners present disclosure has been described above with reference to specific embodiments, which are merely provided for the purpose of understanding the present disclosure and are not intended to limit the present disclosure. It will be possible for those skilled in the art to make variations based on the principle of the present disclosure.

What is claimed is:

1. A sun tracking solar system, comprising
a light focusing device for condensing sunlight incident along an incident light path thereof, and
a solar energy utilization device arranged on the light path behind the light focusing device for utilizing the received light energy,
wherein
the light focusing device comprises a plurality of original light-receiving surfaces, and
further comprises a light guide device arranged on the light path between the light focusing device and the solar energy utilization device for guiding the sunlight condensed by the light focusing device to the solar energy utilization device, and a drive mechanism for driving the light guide device to move with the sun,
the light guide device comprises at least a light guide, the drive mechanism comprises a rail and rotating shafts corresponding to each of the light guides, the rail is arranged between the sun and the plurality of original light-receiving surfaces, the light guide device is move integrally along the rail, and the rotating shaft drives the corresponding light guide to turn to adjust its angle.

2. The solar system of claim 1, wherein
the light focusing device comprises a concave reflector, or
the light focusing device comprises a plurality of planar or concave reflector facing different directions, or
the light focusing device comprises at least a light-focusing refracting surface and a reflecting surface, the light-focusing refracting surface is a tooth surface and contains at least a Fresnel unit, and the type of a reflecting element providing the reflecting surface is selected from a group consisting of: an element with only a single reflection function, and a reflection lens.

3. The solar system of claim 2, wherein
the light focusing device comprises a Fresnel-type reflection lens, and the reflecting surface is coincident with the tooth surface or is arranged on the other surface opposite to the tooth surface;
the form of the macroscopic curve of the Fresnel lens to which the tooth surface belongs is a circumferential symmetry plane or a coaxial surface; and
when the reflecting surface is arranged on the other side opposite to the tooth surface, the type of the reflecting surface is selected from a group consisting of: a planar surface, a concave surface, a convex surface, and a tooth surface.

4. (canceled)

5. The solar system of claim 1, comprising at least one of the following characteristics:
the light guide being horn-shaped, the inner surface thereof being plating with a reflective film, and the reflective film being providing with a transparent protective layer for preventing corrosion; and
each of the original light-receiving surfaces being provided with a corresponding attitude adjustment device which is capable of adjusting the orientation of the original light-receiving surface.

6. The solar system of claim 1, comprising at least one of the following characteristics:
the light focusing device further comprising a front end optical element which is arranged at the most front end in a direction in which the sunlight is incident, and the type of the front end optical element being selected from a group consisting of: a light transmitting shield, and a light-focusing lens; and
the lens in the light focusing device being made of glass, or being made of a transparent plastic material, and a transparent anti-aging coating being arranged on the light-receiving surface of the transparent plastic material; the transparent plastic material being selected from a group consisting of: PMMA, PC, PC/PBT mixture, ABS, and silica gel; and the anti-aging coating being selected from a group consisting of: PVDF, ETFE, PFA, silica gel, and metal coating.

7. The solar system of claim 1, wherein
the solar energy utilization device comprises a solar energy utilization device for receiving sunlight and a thermal energy utilization device for collecting and utilizing thermal energy generated by the photovoltaic conversion apparatus, or
the solar energy utilization device comprises a closed photovoltaic conversion apparatus, the inner surface thereof is composed of a photovoltaic panel, or of a photovoltaic panel and a reflector.

8. The solar system of claim 7, wherein
the photovoltaic conversion apparatus is wrapped in the thermal energy utilization device, or
the system further comprises at least one thermoelectric conversion apparatus provided on a heat conduction path between the photovoltaic conversion apparatus and the thermal energy utilization device, or on a heat conduction path between the thermal energy utilization device and an external cooling device, for using the transmitted thermal energy to generate electricity.

9. The solar system of claim 8, wherein
the cooling device is selected from a group consisting of: a water tank, a steam power generation system, a seawater desalination system, a seawater desalination and power generation system, and a closed thermal cycle power generation system.

10. The solar system of claim 1, wherein the drive mechanism drives the light guide device to move in a manner which is selected from one or two of the following: moving along a predetermined rail, rotary motion, and moving along a straight line.
